(19) United States
(12) Patent Application Publication
(10) Pub. No.: US 2014/0049146 A1
(43) Pub. Date: Feb. 20, 2014

(54) DATA CENTER EQUIPMENT CABINET SYSTEM

(71) Applicants: Mirza Kamaludeen, Burlington (CA); Kumaran Ratnam, Toronto (CA); Karthigesu Vijayasuganthan, Ajax (CA)

(72) Inventors: Mirza Kamaludeen, Burlington (CA); Kumaran Ratnam, Toronto (CA); Karthigesu Vijayasuganthan, Ajax (CA)

(73) Assignee: Cloud Dynamics Inc., Toronto,Ontario, ON (CA)

(21) Appl. No.: 13/818,422

(22) PCT Filed: Sep. 21, 2012
(86) PCT No.: PCT/CA2012/000867

§ 371 Date: Oct. 17, 2013

Related U.S. Application Data
(60) Provisional application No. 61/573,194, filed on Sep. 23, 2011.

(51) Int. Cl. H05K 5/02; H05K 5/00

(52) U.S. Cl. CPC H05K 5/0213; H05K 5/0017
USPC 312/236

(57) ABSTRACT

An equipment cabinet system for housing heat producing computing equipment. The system includes a rectangular shaped cabinet having an interior space defined between opposing top and bottom walls, opposing inner and outer side walls, and opposing front and rear doors. Disposed within the interior space are racks for supporting the computer equipment. The cabinet inner side wall includes an air inlet and an air outlet for air flow into and out of the cabinet interior space. A blower assembly is mounted on the front door disposed within the cabinet interior space, and an airflow directing baffle is provided on the rear door to deflect air flow horizontally towards the first air outlet. A cooling unit having an air-to-fluid heat exchanger provides cold air flow into the interior space of the cabinet and extracts heated air from the interior space of the cabinet.

### RELATED APPLICATION

The application claims the benefit of 35 USC 119(e) to U.S. Provisional Application Ser. No. 61/573194 filed Sep. 23, 2011 (23 Sep. 2011).

### SCOPE OF THE INVENTION

This invention relates to data centers, and more particularly to an equipment cabinet for housing heat producing computing equipment of a data center.

### BACKGROUND OF THE INVENTION

This invention generally relates to the art of data centers, and more specifically to data center equipment cabinets which house banks of servers or other computer equipment. While this invention will be described in the context of data centers, the invention has broader applicability. References to data centers in this specification are therefore to be construed broadly to encompass installations involving telecommunications, or any other equipment assembly using forced air cooling.

Data centers host business critical systems and are required to be available seven days a week, twenty four hours a day, for each day of the year. It is among the highest energy consuming entity in the information technology (“IT”) industry and is also the fastest growing. Approximately 80% of data center operating cost is energy related, of which more than 50% is expended in cooling alone. The computer equipment housed in the data center consumes a lot of power and generates a lot of waste heat. For example, a typical server may consume about 600 Watts per hour (Koomey et al, US Congress Report, 2008) with most data centers having in excess of 7,000 servers. Therefore the annual consumption of a typical data center could be as much as 37,000 Megawatt/year or $3.0 M of IT energy and another $3.0 M for cooling. In addition, the need for maximum availability introduces multiple redundant components at all levels. A typical enterprise data center is designed to uptime Institute Tier III specifications, where there is N+1 of all components and a Tier IV facility has dual redundancy (2N+1), where two redundant components are active at all times with a redundant pair standby for backup. This requirement for redundancy further exuberate the inefficiencies and increased cost associated with operating the data center. Today, a typical datacenter has a Power Utilization Efficiency ratio of 2.4 (Gartner, Burton and McKenzie, 2010). This implies that 2.4 kWatt is supplied to the datacenter for every 1 kWatt consumed at the server. A PUE of 2.8 to 3.1 is not uncommon in older data centers facilities.

In addition, data center efficiencies are typically poor since more than 50% of the power supplied to the facility is used for cooling. A typical data center is generally limited to 2 to 5 kWatt per server cabinet, because of cooling limitations. The resource requirements (time and materials) and the risk of upgrading existing data center facilities only compounds challenges facing the IT industry. Most upgrades typically take between 6 to 24 months, at about a cost of $500,000 and present high user end service risk.

Furthermore, almost 96% of existing data centers are design as rigid secure buildings, where Computer Room Air Conditioner (“CRAC”) units are used to provide cooling. In these designs, IT equipment stored in racks or cabinets re supported by raised floors, where cool air is fed from underneath the floors, therein flooding the room with cold air.

There have been a number of enhancements in recent years to improve the cooling efficiencies of data centers. Among them was the introduction of a sealed equipment cabinet having a heat exchanger contained in the cabinet itself For example, U.S. Pat. No. 7,534,167 proposes a system including a sealed cabinet sized for housing a vertical array of heat-producing units. The cabinet has an exterior shell and the system includes an interior divider wall disposed inside the cabinet, the shell and divider wall providing an equipment chamber adapted to support the array such that the array cooperates with the shell and divider wall in use to define a first plenum. The first plenum having a first inlet defined by the divider wall for receiving a flow of cooling gas and having a first outlet defined by a plurality of openings through the array whereby the first plenum communicates with the openings in use to exhaust substantially all of the flow of cooling fluid through the openings and hence through the array, whereby the divider wall is configured to allow the first inlet to admit the gas to the first plenum in a substantially horizontal direction.

To date, conventional equipment cooling solutions are limited to cope with up to about 2 kW to 10 kW per cabinet. Above this level, it becomes necessary to either spread equipment out widely, which may not be practical or cost effective, or to place restrictive limits on the number of hot devices that can be deployed within a rack or cabinet.

It is against this background that the invention has been devised.

### SUMMARY OF THE INVENTION

To at least partially overcome these disadvantages, in a first aspect, the present invention provides an equipment cabinet system for housing heat producing computing equipment, the system comprising: a rectangular shaped first cabinet having an interior space defined between opposing top and bottom walls, opposing inner and outer side walls, and opposing front and rear doors arranged between the inner and outer side walls of the first cabinet, the first cabinet interior space having disposed therein a vertical array of racks for supporting a first set of the heat producing computer equipment, the first cabinet inner side wall having an open and closable first air inlet spaced towards the front door and an open and closable first air outlet spaced towards the rear door, said first air inlet and said first air outlet allowing for air flow into and out of said first cabinet interior space when in said open position, respectively, the first cabinet interior space being substantially sealed, substantially airtight when said first cabinet front door and said first cabinet rear door are in a closed position and said first air inlet and said first air outlet are in a closed position, respectively, wherein the first cabinet front door has mounted thereon a first blower assembly comprising at least one blower disposed within the first cabinet interior space, the first blower assembly being operable to induce a substantially horizontal air flow through the first set of heat producing computer equipment, wherein the first cabinet rear door has mounted thereon a first airflow directing baffle having a surface oriented to deflect air flow horizontally towards the first air outlet; and a cooling unit in juxtaposed relation to said first cabinet, the cooling unit having an interior space defined between opposing top and bottom walls, opposing first and second side walls, and opposing front and rear doors arranged between the first and second side walls of the cooling unit, the cooling unit comprising a generally centrally disposed heat exchanger assembly extending substantially across a width and height of the cooling unit between the first, second, top and bottom walls of the cooling unit, and a cooling unit blower assembly comprising at least one blower disposed within the cooling unit interior space, the cooling unit blower assembly being operable to induce an air flow through the heat exchanger assembly, wherein the heat exchanger assembly is operable to extract heat from the air flow blown there through, wherein the first side wall is arranged adjacent to the first cabinet inner side wall, the first side wall having a first air exhaust opening in fluid communication with said first air inlet and a first air intake opening in fluid communication with said first air outlet.

In a further aspect of the invention, equipment cabinet system further comprising a rectangular shaped second cabinet in juxtaposed relation to the cooling unit, the second cabinet having an interior space defined between opposing top and bottom walls, opposing inner and outer side walls, and opposing front and rear doors arranged between the inner and outer side walls of the second cabinet, the second cabinet interior space having disposed therein a vertical array of racks for supporting a second set of the heat producing computer equipment, the second cabinet inner side wall having an open and closable second air inlet spaced towards the second cabinet front door and an open and closable second air outlet spaced towards the second cabinet rear door, said second air inlet and said second air outlet allowing for air flow into and out of said second cabinet interior space when in said open position, respectively, the second cabinet interior space being substantially sealed, substantially airtight when said second cabinet front door and said second cabinet rear door are in a closed position and said second air inlet and said second air outlet are in a closed position, respectively, wherein the second cabinet front door has mounted thereon a second blower assembly comprising at least one blower disposed within the second cabinet interior space, the second blower assembly being operable to induce a substantially horizontal air flow through the second set of heat producing computer equipment, wherein the second cabinet rear door has mounted thereon a second airflow directing baffle having a surface oriented to deflect air flow horizontally towards the second air outlet, wherein the second side wall is arranged adjacent to the second cabinet inner side wall, the second side wall having a second exhaust opening in fluid communication with said second air inlet and a second air intake opening in fluid communication with said second air outlet.

In a further aspect of the invention, the first blower assembly is disposed on an associated track mounted to the first cabinet front door, the second blower assembly is disposed on an associated track mounted to the second cabinet front door, whereby each of said at least one blower of said first and second blower assemblies are movable width wise and height wise with respect to the first and second cabinets along said associated tracks, respectively.

In a further aspect of the invention, the first and second blower assemblies each comprise at least three blowers vertically displaced relative to one another.

In a further aspect of the invention, the first airflow directing baffle and the first air outlet each extend height wise substantially from the first cabinet top to the first cabinet bottom wall, and the second airflow directing baffle and the second air outlet each extend height wise substantially from the second cabinet top to the second cabinet bottom wall, wherein the first airflow directing baffle and the second airflow directing baffle each comprise a plurality of horizontally extending channels oriented to deflect air flow horizontally towards the first air outlet and second air outlet, respectively.

In a further aspect of the invention, the cooling unit further comprises a dividing wall extending across a width and height of the cooling unit between the first, second, top and bottom walls of the cooling unit, the dividing wall being spaced forwardly of the first and second air intake openings and defining a high pressure chamber spaced between the dividing wall and the heat exchanger unit, wherein the cooling unit blower assembly is disposed in said dividing wall.

In a further aspect of the invention, the cooling unit blower assembly comprising at least four blowers vertically displaced relative to one another.

In a further aspect of the invention, the cooling unit rear door comprises at least one through hole and an associated closing mechanism to restrict air flow through the at least one opening in the cooling unit rear door, the cooling unit front door comprises at least one through hole and a displaceable airflow directing baffle assembly mounted to the cooling unit front door and being movable to restrict air flow through the at least one opening in the cooling unit front door, wherein the movable baffle assembly is selectively positionable to deflect portions of the air flow through the heat exchanger unit towards at least one of the first air exhaust opening, the second air exhaust opening and the at least one through hole of the front door.

In a further aspect of the invention, the closing mechanism is operable to restrict air flow through the at least one opening in the cooling unit rear door based on an associated position of the displaceable airflow directing baffle assembly and the portion of the air flow directed through the at least one through hole of the cooling unit front door.

In a further aspect of the invention, at least one of the first cabinet outer side wall and the second cabinet outer side wall comprise a heat insulated wall.

In a further aspect of the invention, each of the first cabinet front door, the first cabinet rear door, the second cabinet front door and the second cabinet rear door are biased towards a closed position, wherein each of the first cabinet front door, the first cabinet rear door, the second cabinet front door and the second cabinet rear door comprise a temperature activate locking mechanism operable to be in one of a locked state and an unlocked state responsive to one of a measured rate of temperature change and a measured temperature value of a respective one of the first cabinet interior space and the second cabinet interior space.

In a further aspect of the invention, at least one of the first side wall and the first cabinet inner side wall are integrally formed and the second side wall and the second cabinet inner side wall are integrally formed.

In a further aspect of the invention, at least one of the first side wall and the first cabinet inner side wall are bolted directly together and the second side wall and the second cabinet inner side wall are bolted directly together.

Further aspects of the invention will become apparent upon reading the following detailed description and drawings, which illustrates an exemplary embodiment of this invention.

### BRIEF DESCRIPTION OF THE DRAWINGS

Reference may now be had to the following detailed description taken together with the accompanying drawings in which:

FIG. 1 shows an elevated front perspective view of an equipment cabinet system in accordance with the present invention.

FIG. 2 shows a front plan view of the equipment cabinet system shown in FIG. 1.

FIG. 3 shows a rear plan view of the equipment cabinet system shown in FIG. 1.

FIG. 4 shows an elevated front perspective view of the first cabinet shown in FIG. 1.

FIG. 5a shows a plan view of the inside surface of the first cabinet front door shown in FIG. 4.

FIG. 5b shows a top plan view of the first cabinet front door shown in FIG. 5a.

FIG. 6a shows a plan view of the inside surface of the first cabinet rear door shown in FIG. 4.

FIG. 6b shows a top plan view of the first cabinet rear door shown in FIG. 6a.

FIG. 7 shows an elevated front perspective view of the second cabinet shown in FIG. 1.

FIG. 8a shows a plan view of the inside surface of the second cabinet front door shown in FIG. 7.

FIG. 8b shows top plan view of the inside surface of the second cabinet front door shown in FIG. 8a.

FIG. 9a shows a plan view of the inside surface of the second cabinet rear door shown in FIG. 7.

FIG. 9b shows a top plan view of the second cabinet rear door shown in FIG. 9a.

FIG. 10 shows a top cross-sectional view of the equipment cabinet system shown in FIG. 1.

### DETAILED DESCRIPTION OF THE INVENTION

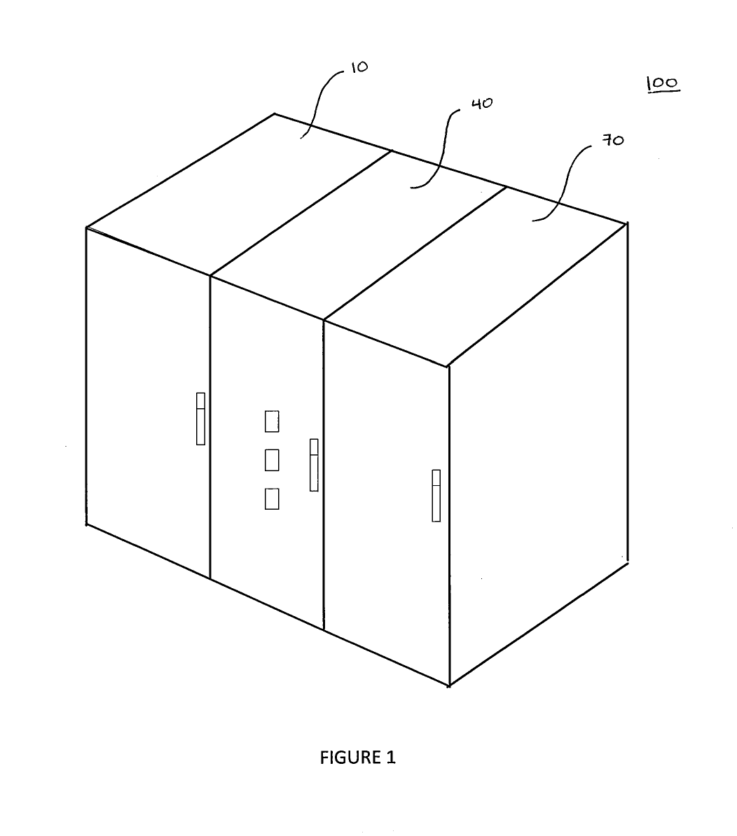

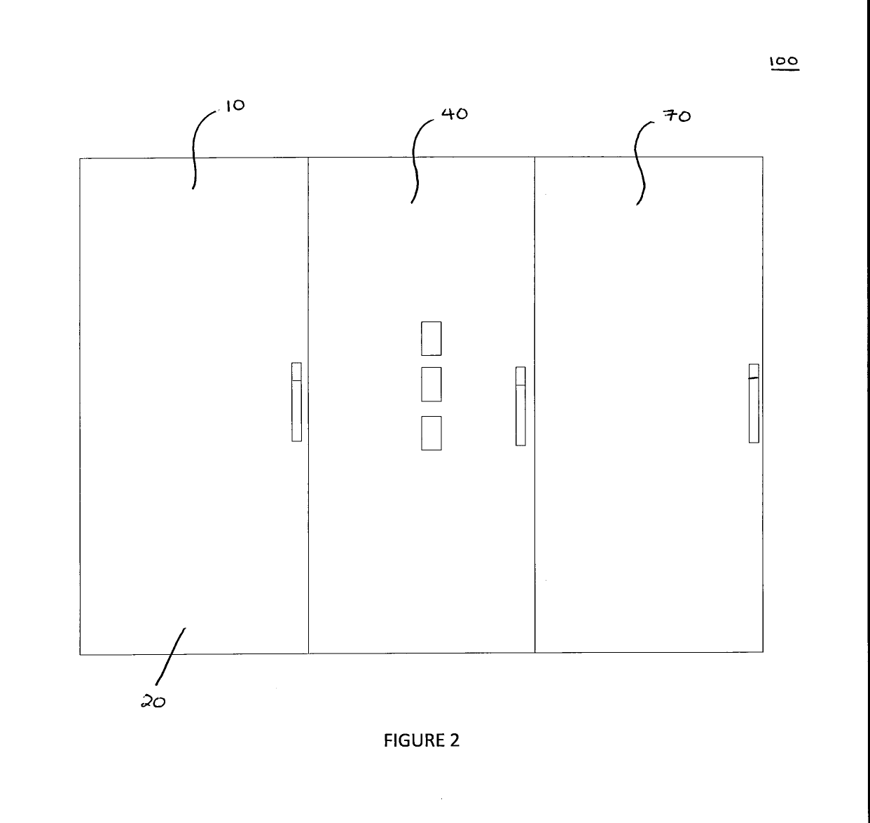

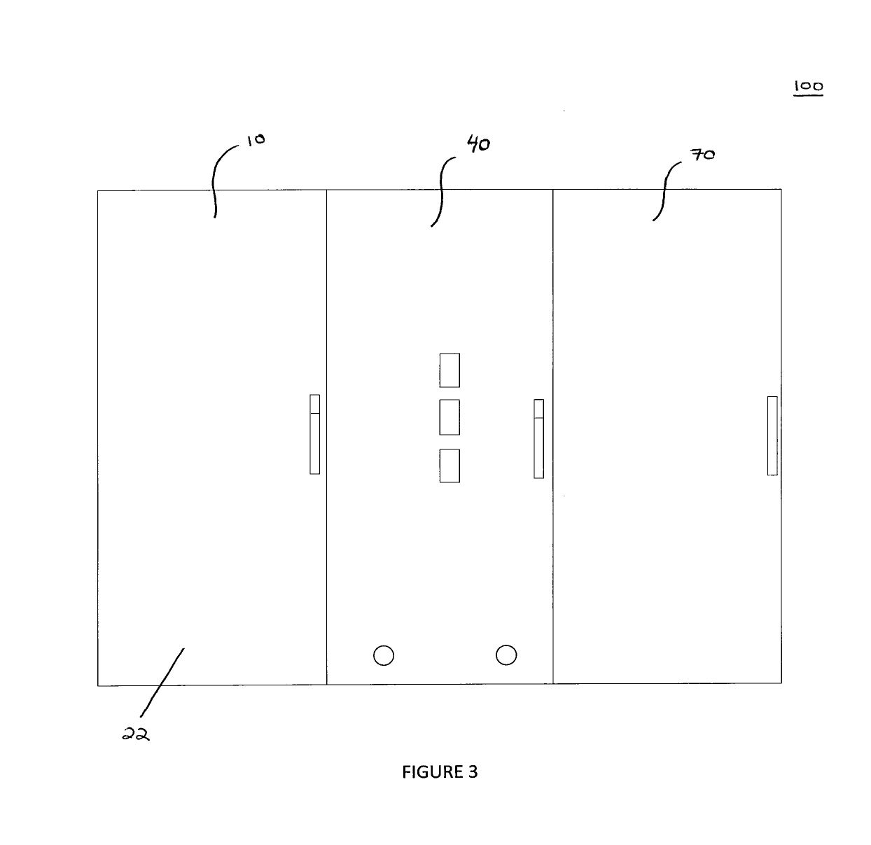

Reference may now be made to FIGS. 1, 2 and 3 which shows an equipment cabinet system 100 in accordance with the present invention. The equipment cabinet system 100 includes in side by side juxtaposed relation, a first cabinet 10, a cooling unit 40, and a second cabinet 70.

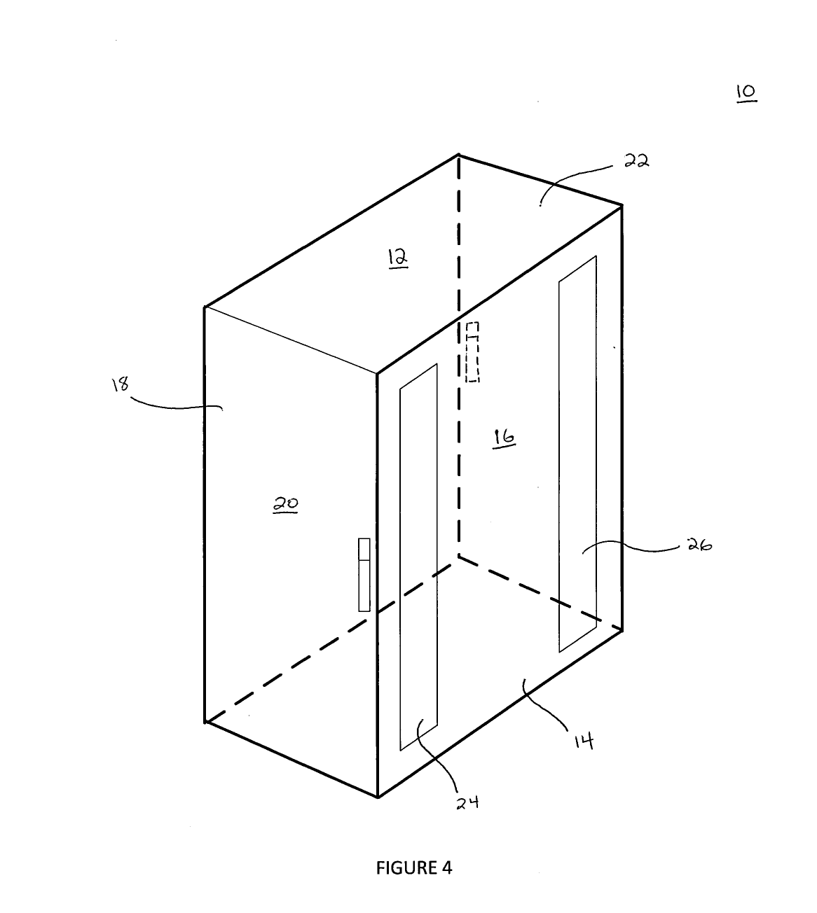

Reference may now be made to FIG. 4 which illustrates the first cabinet 10. The first cabinet 10 has a box-like rectangular shaped having a top wall 12 with an opposing and parallel bottom wall 14, and an inner side wall 16 with an opposing and parallel outer side wall 18. Preferably, the first cabinet outer side wall 18 is a heat insulated wall. Adjustable levelling pads may be provided on a bottom side of the bottom wall 14 for stability and levelling of the first cabinet 10. A hinge mounted front door 20 is arranged between the inner side wall 16 and the outer side wall 18 at a front side of the first cabinet 10. Similarly, a hinge mounted rear door 22 is arranged between the inner side wall 16 and the outer side wall 18 at a rear side of the first cabinet 10. The front door 20 and/or rear door 22 may be constructed of any suitable material, but preferably are made from a transparent material such as a glass or a polymer based material. In a closed position, each of the front door 20 and rear door 22 provides an air tight seal with respect the first cabinet 10.

A first cabinet interior space is defined between the top wall 12, bottom wall 14, inner side wall 16, outer side wall 18, front door 20 and rear door 22. Within the first cabinet interior space there is provided a vertical array of horizontally extending racks (not shown) for supporting a first set of heat producing computer equipment 11, such as computer servers, storage area network (SAN) systems, and network routers. The racks may divide the interior space of the cabinet 10 into separated horizontally extending compartments which may be sealed or isolated from one another.

The first cabinet inner side wall 16 includes an open and closable first air inlet 24 spaced towards and proximal to the front door 20 and an open and closable first air outlet 26 spaced towards and proximal to the rear door 22. Preferably, the first air inlet 24 and/or the first air outlet 26 extend height wise substantially from the first cabinet top wall 12 to the first cabinet bottom wall 14. Each of the first air inlet 24 and first air outlet 26 allow for air flow into and out of the first cabinet interior space when the first air inlet 24 and the first air outlet 26 are open and unrestricted. When the first air inlet 24 and the first air outlet 26 are in a closed position, and thereby restricting air flow into and out of the first cabinet interior space, the first cabinet interior space is substantially sealed and substantially airtight when the first cabinet front door 20 and the first cabinet rear door 22 are also in a closed position, respectively.

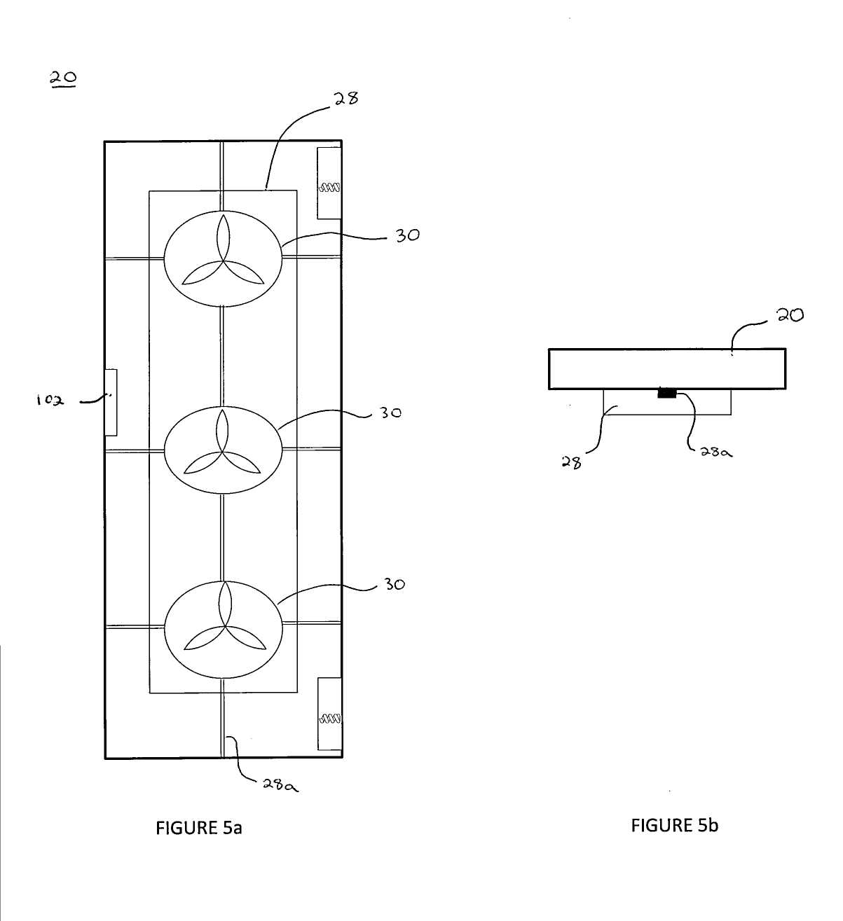

Reference may now be made to FIGS. 5a and 5b. Mounted on an inside surface of the first cabinet front door 20 is a first blower assembly 28. The first blower assembly 28 includes a plurality of blowers 30. Preferably, the first blower assembly 28 includes at least 3 blowers vertically displaced relative to one another. The blower assembly 28 is mounted on an associated track system 28a disposed on the inside surface of the front door 20 so that each of the individual blowers 30 can be selectively positioned relative to the track 28a, as desired. In operation, each blower 30 is disposed within the first cabinet interior space and operable to induce air flow from the blower 30 through the first cabinet interior space towards the rear door 22.

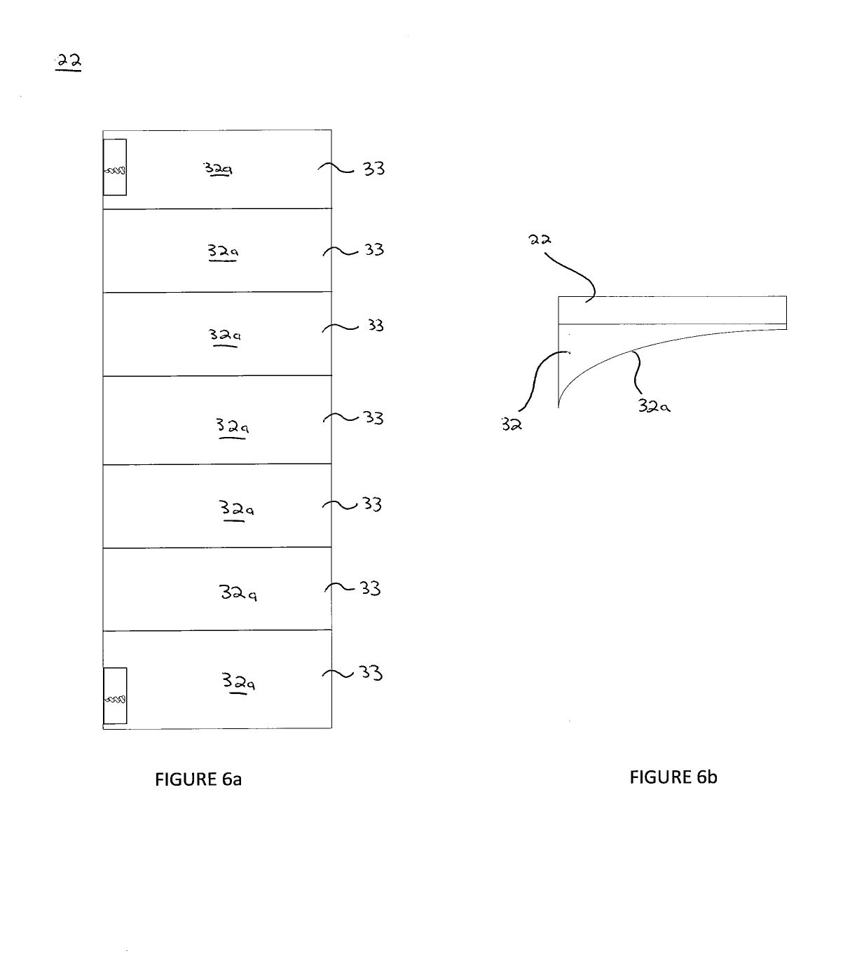

Reference may now be made to FIGS. 6a and 6b. Mounted on an inside surface of the first cabinet rear door 22 is a fixed first airflow directing baffle 32. The airflow directing baffle 32 includes a generally smooth curved surface 32a oriented to deflect impinging air flow horizontally towards the first air outlet 26. Preferably, the first airflow directing baffle 32 extends height wise from the first cabinet top wall 12 to the first cabinet bottom wall 14, and more preferably includes a plurality of horizontally extending channels 33 oriented to deflect air flow horizontally towards the first air outlet 26.

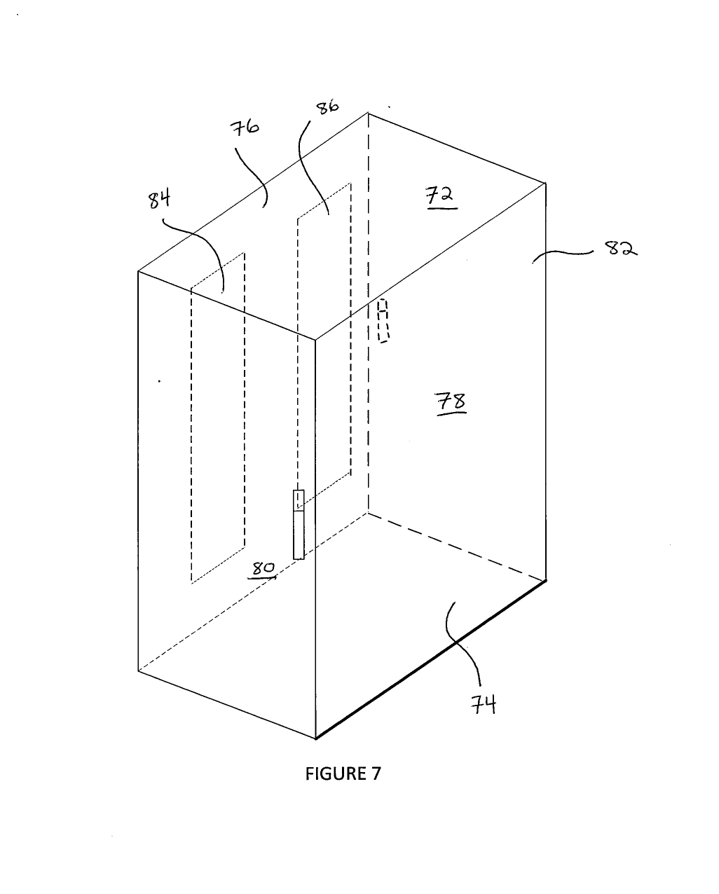

Reference may now be made to FIG. 7. The second cabinet 70 is of a similar construction to the first cabinet 10 and has a box-like rectangular shaped structure having a second cabinet interior space defined between a top wall 72, a bottom wall 74, an inner side wall 76, an outer side wall 78, and hinge mounted front and rear doors 80, 82 arranged between the inner side wall 76 and the outer side wall 78. Preferably, the second cabinet outer side wall 78 is a heat insulated wall. Within the second cabinet interior space there is provided a vertical array of horizontally extending racks (not shown) for supporting a second set of heat producing computer equipment 13.

The second cabinet inner side wall 76 includes an open and closable second air inlet 84 spaced towards and proximal to the front door 80 and an open and closable second air outlet 86 spaced towards and proximal to the rear door 82. Preferably, the second air inlet 84 and/or the second air outlet 86 extend height wise from the first cabinet top wall 12 to the first cabinet bottom wall 14. Each of the second air inlet 84 and the second air outlet 86 allow for air flow into and out of the second cabinet interior space when the second air inlet 84 and the second air outlet 86 are open and unrestricted. When the second air inlet 84 and the second air outlet 86 are a closed position, and thereby restricting air flow into and out of the second cabinet interior space, the second cabinet interior space is substantially sealed and substantially airtight when the second cabinet front door 80 and the second cabinet rear door 82 are also in a closed position, respectively.

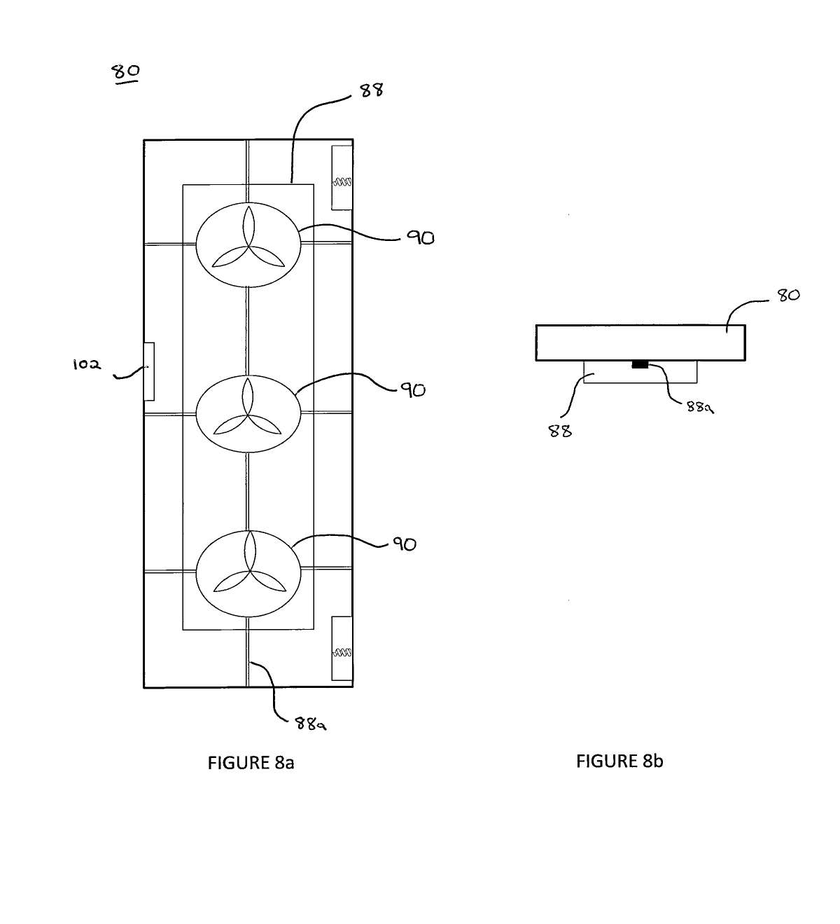

Reference may now be made to FIGS. 8a and 8b. Mounted on an inside surface of the second cabinet front door 80 is a second blower assembly 88. The second blower assembly 88 includes a plurality of blowers 90. Preferably, the second blower assembly 88 includes at least 3 blowers vertically displaced relative to one another. The second blower assembly 88 is mounted on an associated track system 88a disposed on the inside surface of the front door 80 so that each of the individual blowers 90 can be selectively positioned relative to the track 88a, as desired. In operation, each of the blowers 90 are disposed within the second cabinet interior space and induce air flow from the blowers 90 through the second cabinet interior space towards the rear door 82.

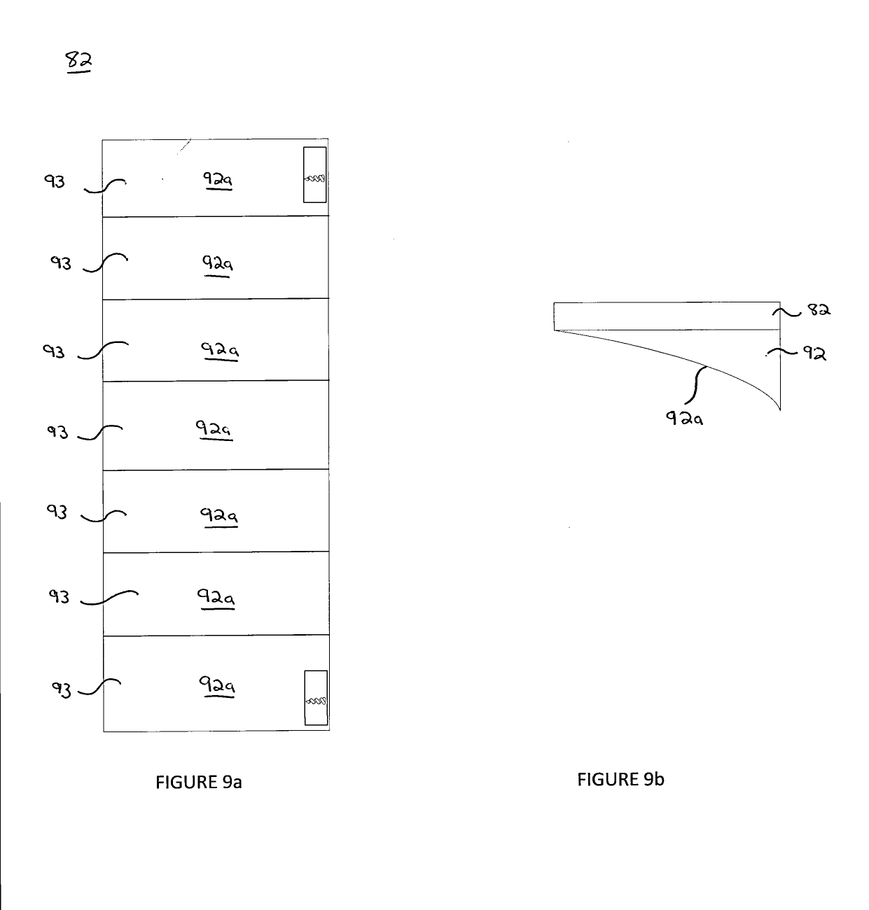

Reference may now be made to FIGS. 9a and 9b. Mounted on an inside surface of the second cabinet rear door 82 is a fixed second airflow directing baffle 92. The airflow directing baffle 92 includes a generally smooth curved surface 922 oriented to deflect impinging air flow horizontally towards the second air outlet 86. Preferably, the second airflow directing baffle 92 extends height wise from the second cabinet top wall 72 to the second cabinet bottom wall 74, and more preferably includes a plurality of horizontally extending channels 93 oriented to deflect air flow horizontally towards the second air outlet 86.

Preferably, each of the first and second cabinet doors 20, 22, 80, 82 are biased towards a closed position and each include a temperature activate locking mechanism 102. The locking mechanism operates between a locked state maintaining the cabinet doors 20, 22, 80, 82 in closed and sealed position and an unlocked state where the doors are biased to be in an open position. The locking mechanism 102 preferably is responsive to one of a measured rate of temperature change and a measured temperature value within the associated first cabinet interior space or the second cabinet interior space.

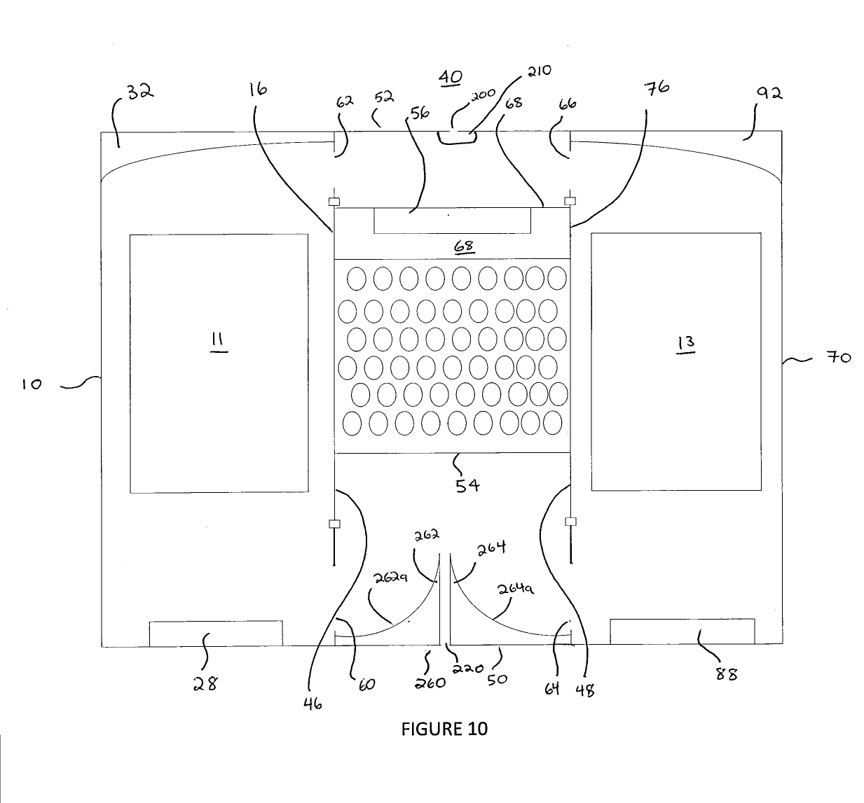

Reference can now be made to FIG. 10. The cooling unit 40 is interposed between the first cabinet inner side wall 16 and the second cabinet inner side wall 76. The cooling unit 40 includes an interior space defined between opposing top and bottom walls 42, 44, opposing first and second side walls 46, 48 and opposing front and rear doors 50, 52 arranged between the first side wall 46 and second side wall 48. The first side wall 46 is arranged adjacent to and in juxtaposed relation to the first cabinet inner side wall 16. The first side wall 46 includes a first air exhaust opening 60 and a first air intake 62 which are aligned in mating relation to the first air inlet 24 and the first air outlet 26, respectively, such that they are in fluid communication with one another. Similarly, the second side wall 48 includes a second air exhaust opening 64 and a second air intake opening 66 which are aligned in mating relation to the second air inlet 84 and the second air outlet 86, respectively, such that they are in fluid communication with one another. Accordingly, the cooling unit interior space is in fluid communication with the first cabinet interior space and the second cabinet interior space, respectively. Preferably, the first side wall 46 and the first cabinet inner side wall 16 are integrally formed as a common wall and the second side wall 48 and the second cabinet inner side wall 76 are integrally formed as a common wall. Alternatively, in a more preferred embodiment, the first side wall 46 and the first cabinet inner side wall 16 are bolted directly together and the second side wall 76 and the second cabinet inner side wall 16 are bolted directly together.

Centrally arranged within the cooling unit interior space is an air to fluid heat exchanger assembly 54. The heat exchanger assembly 54 generally extends across the entire width and height of the cooling unit 40 between the first side wall 46, second side wall 48, top wall 42 and bottom wall 44 of the cooling unit 40.

A dividing wall 68 extends across the width and height of the cooling unit 40 between the first side wall 46, second side wall 48, top wall 42 and bottom wall 44 of the cooling unit. The dividing wall 68 is spaced forwardly of the first air intake opening 62 and the second air intake opening 66. A cooling unit blower assembly 56 comprising at least one blower disposed within the dividing wall 68. In operation, the blowers of the blower assembly 56 are arranged to induce an air flow through the heat exchanger assembly 54, and the heat exchanger assembly 54 is operable to extract and transfer heat from the air flow blown there through into a fluid circulating through the heat exchanger assembly 54. Accordingly, a high pressure chamber 68a spaced between the dividing wall 68 and the heat exchanger assembly 54 is formed when the blower assembly 56 is operated. Preferably, the cooling unit blower assembly 56 includes at least four blowers vertically displaced relative to one another.

Mounted on an inside surface of the cooling unit front door 50 is a displaceable airflow directing baffle assembly 260 which is disposed within the cooling unit interior space when the front door 50 is in a closed position. The front door 50 is provided with at least one opening 220 to the exterior of the cooling unit 40. Preferably, the baffle assembly 260 extends height wise from the cooling unit top wall 42 to the cooling unit bottom wall 44. The baffle assembly includes corresponding left and right side baffles 262, 264 with each baffle 262, 264 being mounted on an associated horizontally extending track. Each baffle 262, 264 being independently movable along the associated track between a position to over the opening 200 thereby restricting air flow through the opening 220 in the cooling unit front door 50 and a position blocking the first air inlet 24 and second air inlet 84, respectively.

The movable baffles 262, 264 each having a generally smooth curved surface 262a, 264a oriented to deflect the impinging air flow horizontally towards either the first air exhaust opening 60 and the second air exhaust opening 64, respectively. In operation, the baffles 262, 264 of the baffles assembly 260 are selectively positionable along the associated tracks to deflect varying/desired portions of the air flow through the heat exchanger assembly 54 towards the first air exhaust opening 60, the second air exhaust opening 64 and the opening 220 through the front door 50.

The cooling unit rear door 52 includes at least one opening 200 to the exterior of the cooling unit 40. A closing mechanism 210 is mounted to the rear door 52 and operable to restrict the amount of air flow through the opening 200 in response to the portion of air flow through the opening 200 of the front door 50. Preferably, the closing mechanism 210 comprises an air flow valve operable to restrict air flow through the at least one opening 200 in the cooling unit rear door 52 based on an associated position of the baffles 262, 264 of the airflow directing baffle assembly 260. More preferably, the closing mechanism 210 is a baffle assembly mirroring the structure and movement of the baffle assembly 260.

In operation, air heated by the computing equipment is sucked into the cooling unit 40 from the adjacent first and second equipment cabinets 10, 70 through the rear air inlet/intake openings 24, 84, 62, 66 by means the blower assembly 56. The heated air is then blown through the heat exchanger assembly 54 by the blower assembly 56 where fluid cooled fins remove/transfer the heat from the air stream into the fluid circulating through the heat exchanger assembly 54. The air blown through the heat exchanger assembly 54, now cooled, impinges on the displaceable airflow directing baffles 262, 264 which deflect, based on their position along their associated tracks, selected portions of the flowing air horizontally between the first and second cabinets 10, 70 and through the opening 220. The first blower assembly 28 and the second blower assembly 88 push the cooled air now in the respective equipment cabinet 10, 70 spaces horizontal through the computer equipment 11, 13 respectively. The air flow is heated as it passes through the computing equipment 11, 13 and impinges the on directing baffles 32, 92 which directed the re-heated air horizontally towards and into the cooling unit 40.

The amount of cooling provided by the cooling unit 40 is proportional to the amount of cooling fluid circulated through the heat exchanger assembly 54 (“cooling fluid flow rate”) and the amount of air flow (“air flow rate”) which is pushed through the heat exchanger assembly 54 by the blower assembly 56 (blower speed). The amount of heat produced by the computing equipment 11, 13 is proportional to the computer equipment utilization and/or the amount of power consumed by the computer equipment 11, 13. The power consumption and/or computer equipment utilization of the computing equipment 11, 13 are directly measurable, as for example by measuring power consumed at a power plug receptacle a server is plugged into and/or determined by provisioning API software/application running a cloud instance. The cooling unit 40 is provided with a control system which monitors the amount of computer equipment power consumed by the equipment 11, 13 and/or computer equipment utilization as determined by the provisioning software and determines the cooling fluid flow rate and the air flow rate based on the measured power consumption and/or computer equipment utilization. Preferably, the control system determines the computing equipment percentage utilization and/or power consumption, determines the heat load of the equipment 11, 13 based on the equipment percentage utilization and/or power consumption, and subsequently regulates the cooling fluid flow rate and air flow rate (blower assembly 56 speed) to optimize energy consumption. With the forgoing control system, the cooling capacity of the cooling unit 40 is proactive rather then a reactive system which adjusts the cooling fluid flow rate and air flow rate based on temperature reading (i.e. the computer equipment exceeding a set temperature.

To the extent that a patentee may act as its own lexicographer under applicable law, it is hereby further directed that all words appearing in the claims section, except for the above defined words, shall take on their ordinary, plain and accustomed meanings (as generally evidenced, inter alia, by dictionaries and/or technical lexicons), and shall not be considered to be specially defined in this specification. Notwithstanding this limitation on the inference of “special definitions,” the specification may be used to evidence the appropriate, ordinary, plain and accustomed meanings (as generally evidenced, inter alia, by dictionaries and/or technical lexicons), in the situation where a word or term used in the claims has more than one pre-established meaning and the specification is helpful in choosing between the alternatives.

It will be understood that, although various features of the invention have been described with respect to one or another of the embodiments of the invention, the various features and embodiments of the invention may be combined or used in conjunction with other features and embodiments of the invention as described and illustrated herein.

Although this disclosure has described and illustrated certain preferred embodiments of the invention, it is to be understood that the invention is not restricted to these particular embodiments. Rather, the invention includes all embodiments, which are functional, electrical or mechanical equivalents of the specific embodiments and features that have been described and illustrated herein.

We claim:

1. An equipment cabinet system for housing heat producing computing equipment, the system comprising:
a rectangular shaped first cabinet having an interior space defined between opposing top and bottom walls, opposing inner and outer side walls, and opposing front and rear doors arranged between the inner and outer side walls of the first cabinet, the first cabinet interior space having disposed therein a vertical array of racks for supporting a first set of the heat producing computer equipment, the first cabinet inner side wall having an open and closable first air inlet spaced towards the front door and an open and closable first air outlet spaced towards the rear door, said first air inlet and said first air outlet allowing for air flow into and out of said first cabinet interior space when in said open position, respectively, the first cabinet interior space being substantially sealed, substantially airtight when said first cabinet front door and said first cabinet rear door are in a closed position and said first air inlet and said first air outlet are in a closed position, respectively,
wherein the first cabinet front door has mounted thereon a first blower assembly comprising at least one blower disposed within the first cabinet interior space, the first blower assembly being operable to induce a substantially horizontal air flow through the first set of heat producing computer equipment,
wherein the first cabinet rear door has mounted thereon a first airflow directing baffle having a surface oriented to deflect air flow horizontally towards the first air outlet; and
a cooling unit in juxtaposed relation to said first cabinet, the cooling unit having an interior space defined between opposing top and bottom walls, opposing first and second side walls, and opposing front and rear doors arranged between the first and second side walls of the cooling unit, the cooling unit comprising a generally centrally disposed heat exchanger assembly extending substantially across a width and height of the cooling unit between the first, second, top and bottom walls of the cooling unit, and a cooling unit blower assembly comprising at least one blower disposed within the cooling unit interior space, the cooling unit blower assembly being operable to induce an air flow through the heat exchanger assembly, wherein the heat exchanger assembly is operable to extract heat from the air flow blown there through, wherein the first side wall is arranged adjacent to the first cabinet inner side wall, the first side wall having a first air exhaust opening in fluid communication with said first air inlet and a first air intake opening in fluid communication with said first air outlet.

2. The system according to claim 1, further comprising a rectangular shaped second cabinet in juxtaposed relation to the cooling unit, the second cabinet having an interior space defined between opposing top and bottom walls, opposing inner and outer side walls, and opposing front and rear doors arranged between the inner and outer side walls of the second cabinet, the second cabinet interior space having disposed therein a vertical array of racks for supporting a second set of the heat producing computer equipment, the second cabinet inner side wall having an open and closable second air inlet spaced towards the second cabinet front door and an open and closable second air outlet spaced towards the second cabinet rear door, said second air inlet and said second air outlet allowing for air flow into and out of said second cabinet interior space when in said open position, respectively, the second cabinet interior space being substantially sealed, substantially airtight when said second cabinet front door and said second cabinet rear door are in a closed position and said second air inlet and said second air outlet are in a closed position, respectively,
wherein the second cabinet front door has mounted thereon a second blower assembly comprising at least one blower disposed within the second cabinet interior space, the second blower assembly being operable to induce a substantially horizontal air flow through the second set of heat producing computer equipment,
wherein the second cabinet rear door has mounted thereon a second airflow directing baffle having a surface oriented to deflect air flow horizontally towards the second air outlet,
wherein the second side wall is arranged adjacent to the second cabinet inner side wall, the second side wall having a second exhaust opening in fluid communication with said second air inlet and a second air intake opening in fluid communication with said second air outlet.

3. The system according to claim 2, wherein the first blower assembly being disposed on an associated track mounted to the first cabinet front door, the second blower assembly being disposed on an associated track mounted to the second cabinet front door, whereby each of said at least one blower of said first and second blower assemblies are movable width wise and height wise with respect to the first and second cabinets along said associated tracks, respectively.

4. The system according to claim 3, wherein said first and second blower assemblies each comprise at least 3 blowers vertically displaced relative to one another.

5. The system according to claim 2, wherein the first airflow directing baffle and the first air outlet each extend height wise substantially from the first cabinet top wall to the first cabinet bottom wall, and the second airflow directing baffle and the second air outlet each extend height wise substantially from the second cabinet top wall to the second cabinet bottom wall, wherein the first airflow directing baffle and the second airflow directing baffle each comprise a plurality of horizontally extending channels oriented to deflect air flow horizontally towards the first air outlet and second air outlet, respectively.

6. The system according to claim 2, wherein the cooling unit further comprises a dividing wall extending across a width and height of the cooling unit between the first, second, top and bottom walls of the cooling unit, the dividing wall being spaced forwardly of the first and second air intake openings and defining a high pressure chamber spaced between the dividing wall and the heat exchanger unit, wherein the cooling unit blower assembly is disposed in said dividing wall.

7. The system according to claim 3, wherein the cooling unit blower assembly comprising at least 4 blowers vertically displaced relative to one another.

8. The system according to claim 2, wherein the cooling unit rear door comprises at least one through hole and an associated closing mechanism to restrict air flow through the at least one opening in the cooling unit rear door, the cooling unit front door comprises at least one through hole and a displaceable airflow directing baffle assembly mounted to the cooling unit front door and being movable to restrict air flow through the at least one opening in the cooling unit front door, wherein the movable baffle assembly is selectively positionable to deflect portions of the air flow through the heat exchanger assembly towards at least one of the first air exhaust opening, the second air exhaust opening and the at least one through hole of the front door.

9. The system according to claim 8, wherein the closing mechanism is operable to restrict air flow through the at least one opening in the cooling unit rear door based on an associated position of the displaceable airflow directing baffle assembly and the portion of the air flow directed through the at least one through hole of the cooling unit front door.

10. The system according to claim 2, wherein at least one of the first cabinet outer side wall and the second cabinet outer side wall comprise a heat insulated wall.

11. The system according to claim 2, wherein each of the first cabinet front door, the first cabinet rear door, the second cabinet front door and the second cabinet rear door are biased towards a closed position, wherein each of the first cabinet front door, the first cabinet rear door, the second cabinet front door and the second cabinet rear door comprise a temperature activate locking mechanism operable to be in one of a locked state and an unlocked state responsive to one of a measured rate of temperature change and a measured temperature value of a respective one of the first cabinet interior space and the second cabinet interior space.

12. The system according to claim 2, wherein at least one of the first side wall and the first cabinet inner side wall are integrally formed and the second side wall and the second cabinet inner side wall are integrally formed.

13. The system according to claim 2, wherein at least one of the first side wall and the first cabinet inner side wall are bolted directly together and the second side wall and the second cabinet inner side wall are bolted directly together.

14. The system according to claim 2, further comprising a control system, the control system including a monitor for measuring power consumed by the computer equipment, wherein at least one of a cooling fluid flow rate through heat exchanger assembly and blower speed of the cooling unit blower assembly are determined based on the measure power consumption.

15. The system according to claim 14, wherein the monitor comprises a measurable power distribution unit.
